(19) United States
(12) Patent Application Publication
(10) Pub. No.: US 2026/0031311 A1
(43) Pub. Date: Jan. 29, 2026

(54) PLASMA MONITORING AND PLASMA DENSITY MEASUREMENT IN PLASMA PROCESSING SYSTEMS

(71) Applicants: LAM RESEARCH CORPORATION, Fremont, CA (US); HANYANG UNIVERSITY, Seoul (KR)

(72) Inventors: Hak-sung KIM, Seoul (KR); Dong-woon PARK, Seoul (KR); Heon-su KIM, Seoul (KR); Sang-il KIM, Seoul (KR); Jindoo CHOI, Alameda, CA (US); Fabio RIGHETTI, Redwood City, CA (US)

(21) Appl. No.: 18/995,541

(22) PCT Filed: Jul. 18, 2023
(86) PCT No.: PCT/US2023/028018

§ 371 Date: Jan. 16, 2025

Related U.S. Application Data
(60) Provisional application No. 63/390,337, filed on Jul. 19, 2022.

(51) Int. Cl. H01J 37/32

(52) U.S. Cl. CPC H01J 37/32972; H01J 37/3211; H01J 37/32174; H01J 37/32449; H01J 37/3299

(57) ABSTRACT

A plasma processing system includes a processing chamber including a substrate support. A plasma generator is configured to selectively generate plasma in the processing chamber to treat a substrate arranged on the substrate support. An emitter is configured to transmit first terahertz waves through the plasma in the processing chamber. A detector is configured to receive second terahertz waves corresponding to the first terahertz waves transmitted through the plasma in the processing chamber.

### CROSS-REFERENCE TO RELATED APPLICATIONS

This application claims the benefit of U.S. Provisional Application No. 63/390,337, filed on Jul. 19, 2022. The entire disclosure of the above application is incorporated herein by reference.

### FIELD

The present disclosure relates to plasma processing systems, and more particularly to plasma monitoring and plasma density measurement in plasma processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems are used to perform treatments on substrates such as semiconductor wafers. Examples of treatments include deposition, etching, cleaning, or other substrate treatments. During processing, a substrate is arranged on a substrate support in a processing chamber. A gas delivery system supplies process gases to the processing chamber to expose the substrate. A radio frequency (RF) plasma generator may be used to strike plasma in the processing chamber to cause chemical reactions to occur.

Variations in plasma density during the process may alter the effect of the substrate treatment from one substrate to another and/or in different areas of the same substrate. Therefore, maintaining consistent plasma density during processing is important. Optical emission spectroscopy (OES) has been used to monitor a state of the plasma during processing. OES is an indirect monitoring technique that is capable of monitoring plasma intensity inside of the processing chamber based on light generated by the plasma. Variations in the plasma intensity may cause changes in film quality. Plasma monitoring accuracy using OES decreases as the distance from the monitoring position to the center of the processing chamber increases.

### SUMMARY

A plasma processing system includes a processing chamber including a substrate support. A plasma generator is configured to selectively generate plasma in the processing chamber to treat a substrate arranged on the substrate support. An emitter is configured to transmit first terahertz waves through the plasma in the processing chamber. A detector is configured to receive second terahertz waves corresponding to the first terahertz waves transmitted through the plasma in the processing chamber.

In other features, the emitter and the detector are arranged on opposite sides of the processing chamber. The processing chamber includes first and second windows located adjacent to the emitter and the detector, respectively. The first terahertz waves pass through the first window and into the processing chamber. The detector is configured to receive the second terahertz waves through the second window.

In other features, an optical axis of the first window is aligned with a path of the first terahertz waves. The emitter and the detector are arranged inside of the processing chamber. The emitter includes a plurality of sub-emitters each configured to generate the first terahertz waves. The detector includes a plurality of sub-detectors configured to detect the second terahertz waves from each of the plurality of sub-emitters, respectively.

In other features, a first path of the first terahertz waves from one sub-emitter of the plurality of sub-emitters is configured to pass over a center of a substrate. A second path of the first terahertz waves transmitted from another sub-emitter of the plurality of sub-emitters is configured to pass over an edge of the substrate.

In other features, a first path of the first terahertz waves from one sub-emitter of the plurality of sub-emitters is closer to an upper portion of the processing chamber than a second path of the first terahertz waves from another sub-emitter of the plurality of sub-emitters. The emitter and the detector are arranged above a surface of a substrate. The first terahertz waves from the emitter are directed at and reflected by the substrate.

In other features, the detector is configured to detect the second terahertz waves using frequency scanning. A controller configured to control the emitter and the detector and to compare one or more characteristics of the second terahertz waves to one or more corresponding characteristics of reference terahertz waves and to estimate plasma density in response to the comparison. The controller is configured to determine an amplitude difference between the second terahertz waves and the reference terahertz waves and calculate the plasma density in the processing chamber based on the amplitude difference.

In other features, the controller is configured to determine an RMS value difference between the second terahertz waves and the reference terahertz waves and calculate the plasma density in the processing chamber based on the RMS value difference.

In other features, the controller is configured to determine a phase difference between the second terahertz waves and the reference terahertz waves and calculate the plasma density in the processing chamber based on the phase difference. The first terahertz waves are configured as continuous waves.

In other features, the plasma generator includes a coil arranged adjacent to the processing chamber and an RF generator configured to supply power to the coil. The controller is further configured to adjust power supplied by the RF generator to the coil in response to the plasma density. The controller is further configured to communicate with a gas delivery system to adjust a gas flow rate to the processing chamber in response to the plasma density.

A method for measuring plasma density comprising arranging a substrate on a substrate support in a processing chamber; striking plasma in the processing chamber; transmitting first terahertz waves through the plasma in the processing chamber; receiving second terahertz waves corresponding to the first terahertz waves transmitted through the plasma; and determining plasma density based on characteristics of the second terahertz waves.

The method includes measuring reference terahertz waves transmitted through the processing chamber before generating the plasma in the processing chamber. The determining the plasma density includes at least one of comparing an amplitude of the second terahertz waves with an amplitude of the reference terahertz waves; or comparing a phase of the second terahertz waves with a phase of the reference terahertz waves.

In other features, the plasma density is proportional to a difference between the amplitude of the reference terahertz waves and the amplitude of the second terahertz waves. The amplitude of the second terahertz waves is smaller than the amplitude of the reference terahertz waves. As the plasma density in the processing chamber increases, a transmittance of the second terahertz waves decreases and the difference between the amplitude of the reference terahertz waves and the amplitude of the second terahertz waves increases. The plasma density is proportional to a difference between the phase of the reference terahertz waves and the phase of the second terahertz waves.

In other features, the phase of the second terahertz waves is different than the phase of the reference terahertz waves. As the plasma density in the processing chamber increases, a transmittance of the second terahertz waves decreases and the phase difference between the reference terahertz waves and the second terahertz waves increases. The method includes receiving the second terahertz waves includes outputting the first terahertz waves into the processing chamber from an emitter arranged on one side of the processing chamber; and detecting the second terahertz waves transmitted through the processing chamber from a detector arranged on the other side of the processing chamber. A path of the second terahertz waves between the emitter and the detector passes over the substrate.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example of a plasma processing system for monitoring plasma density according to the present disclosure;

FIG. 2 is a functional block diagram of an example of a plasma processing system for monitoring plasma density according to the present disclosure;

FIG. 3 is a functional block diagram and signal diagram of an example of a terahertz wave measuring system of a plasma processing system according to the present disclosure;

FIG. 4 is a flowchart illustrating an example of a method for measuring plasma density of plasma generated by a plasma processing system according to the present disclosure;

FIGS. 5 and 6 are functional block diagrams of examples of a plasma processing system performing plasma density measurement according to the present disclosure;

FIGS. 7 to 10 are graphs showing examples of measurement results of a reference terahertz wave and a measured terahertz wave of the plasma processing system according to the present disclosure;

FIG. 11 is a schematic block diagram of another example of a plasma processing system according to the present disclosure;

FIGS. 12 and 13 are schematic plan views of another example of a plasma processing system according to the present disclosure; and

FIG. 14 is a functional block diagram of another example of a plasma processing system according to the present disclosure.

In the drawings, reference numbers may be reused to identify similar and/or identical elements.

### DETAILED DESCRIPTION

Terahertz waves are electromagnetic waves located between microwaves and infrared rays. Terahertz waves have frequencies from about 0.1 THz to about 10.0 THz. While terahertz waves are absorbed by moisture, terahertz waves have non-metal material penetrating characteristics and can be used to observe objects that are not capable of being sensed using visible light.

Plasma processing systems according to the present disclosure determine the plasma density in a processing chamber based on changes in characteristics of the terahertz waves passing through the plasma in the processing chamber. In addition, the plasma processing system according to the present disclosure can selectively transmit terahertz waves through one or more local areas of the processing chamber to monitor the plasma in the corresponding local areas.

According to some examples, the plasma processing system includes a processing chamber including a substrate support with a substrate arranged thereon. A radio frequency (RF) plasma generator is configured to generate plasma in the processing chamber to treat the substrate. An emitter is configured to transmit terahertz waves through the plasma in the processing chamber. A detector is configured to receive the terahertz waves transmitted through the plasma in the processing chamber.

According to another aspect of the present disclosure, a method for measuring plasma density includes arranging a substrate on a substrate support in a processing chamber and striking plasma in the processing chamber. The method includes transmitting terahertz waves through the plasma and determining plasma density based on characteristics of received terahertz waves and reference terahertz waves.

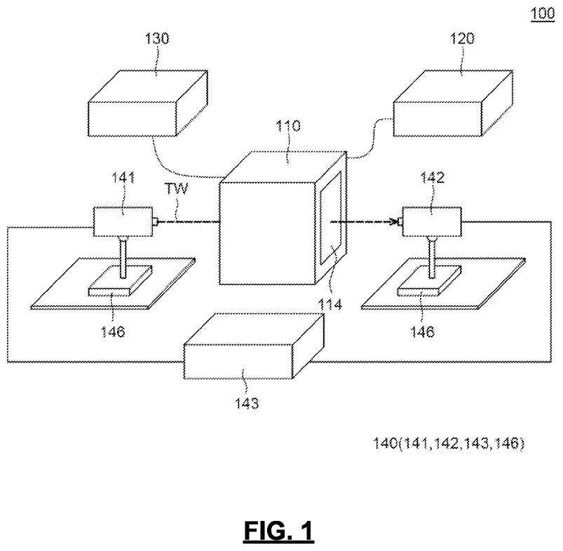

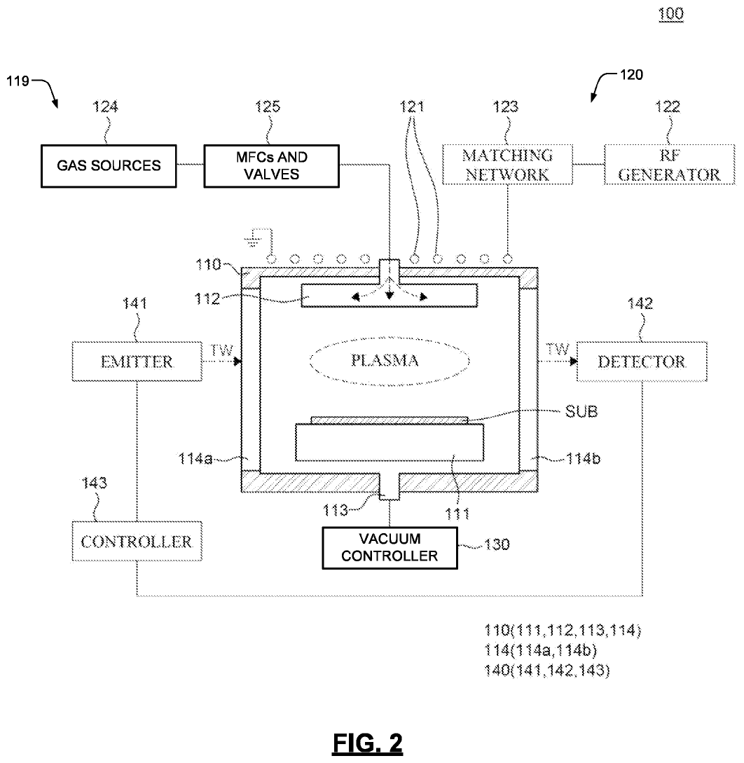

Referring to FIGS. 1 and 2, the plasma processing system 100 includes a processing chamber 110, an RF plasma generator 120, a vacuum controller 130, and a terahertz wave measurement system 140. The processing chamber 110 provides a processing volume that is maintained in a vacuum state by the vacuum controller 130. The processing chamber 110 also contains the plasma. For example, a semiconductor process such as an etching process or a deposition process (such as plasma enhanced chemical vapor deposition (PECVD)) may be performed by generating the plasma in the processing chamber 110.

The processing chamber 110 includes a substrate support 111, a gas distribution device 112, an exhaust 113, and a window 114. The substrate support 111 supports a substrate SUB during processing. In some examples, the gas distribution device 112 may include a showerhead including a stem portion (with a vertical gas channel) extending downwardly from a top surface of the processing chamber 110, a base portion extending radially outwardly from the stem portion, and a faceplate including gas through holes. A gas plenum is defined between the base portion and the faceplate. In other examples, a gas injector or other device can be used.

The substrate support 111 may include an electrostatic chuck including electrodes that are energized to hold (or chuck) the substrate and deenergized to release (or dechuck) the substrate SUB. The substrate support 111 may also include coolant channels and/or resistive heaters (not shown) arranged in one or more zones to adjust a temperature of the substrate during processing. The substrate support 111 may include a lifting system (not shown) configured to adjust a distance between the substrate SUB and the gas distribution device 112.

The gas distribution device 112 is configured to inject and disburse gas from a gas delivery system 119 including one or more gas sources 124 and one or more mass flow controller(s) and valve(s) 125 into the processing chamber 110. The exhaust 113 is configured to control pressure in the processing chamber 110. The exhaust 113 is connected to the vacuum controller 130 to control the pressure in the processing chamber 110. In some examples, the vacuum controller 130 includes a pump and a valve (not shown). Process gases, purge gases, and reaction byproducts in the processing chamber 110 are evacuated from the processing chamber 110 through the exhaust 113.

The window 114 is arranged in one or more side surfaces of the processing chamber 110 to transmit terahertz waves TW into the processing chamber 110. When the terahertz waves TW are transmitted through the processing chamber while plasma is present, characteristics of the terahertz waves TW change (relative to reference terahertz waves that do not pass through the plasma) depending on plasma density.

The window 114 may be arranged adjacent to an emitter 141 and a detector 142 of the terahertz wave measurement system 140. For example, the window 114 may include a first window 114a arranged adjacent to the emitter 141 of the terahertz wave measurement system 140 and a second window 114b arranged adjacent to the detector 142. The first window 114a may be arranged on one side of the processing chamber 110, and the second window 114b may be arranged on the other side of the processing chamber 110.

An optical axis of the window 114 may be configured to align with a path of the terahertz waves TW. When the optical axis of the window 114 is different than a path of the terahertz waves TW, polarization of the terahertz waves TW may be distorted by a birefringence characteristic, which makes it more difficult to accurately measure the plasma density. Accordingly in some examples, the optical axis of the window 114 is configured to align with the path of the terahertz waves TW to maintain a polarization direction of the terahertz waves TW.

In some examples, the window 114 may be made using Z-cut quartz that is cut in a direction parallel to a crystal direction. Since the Z-cut quartz has an optical axis that is perpendicular to a plane of the incident terahertz waves TW, the terahertz waves TW pass through the window 114 without a change in the optical axis. However, the window 114 may be also made of materials other than the Z-cut quartz.

The RF plasma generator 120 is configured to generate plasma in the processing chamber 110. A gas delivery system 119 includes one or more gas sources 124 to supply process and one or more mass flow controller(s) and/or valve(s) 125 to meter one or more gases. In examples using inductively coupled plasma (ICP), the RF plasma generator 120 generates the plasma by applying RF energy to the gas supplied to the processing chamber 110. The RF plasma generator 120 includes a coil 121, an RF generator 122, and a matching network 123. The coil 121 is arranged outside of and adjacent to the processing chamber 110. Current flowing through the coil 121 generates an induced magnetic field around the coil 121, and the induced magnetic field ionizes the gas in the processing chamber 110 to generate the plasma.

The RF generator 122 is configured to supply power to the coil 121. The RF generator 122 may supply power to the coil 121 through the matching network 123. The matching network 123 is coupled between the coil 121 and the RF generator 122. The impedances of the RF generator 122, the coil 121, and the processing chamber 110 are matched by adjusting a capacitance of the matching network 123.

The process gas for generating the plasma is stored in the one or more gas sources 124. The gas stored in the gas sources 124 is supplied to the processing chamber 110 using the mass flow controller(s) and/or valve(s) 125, and the gas distribution device 112. A manifold (not shown) may be used to mix the gases and can be located between the mass flow controller(s) and/or valve(s) 125 and the gas distribution device 112.

The mass flow controller(s) and/or valve(s) 125 control the gas flow rate of the gas sources 124 to the processing chamber 110. The plasma density in the processing chamber 110 may be adjusted by varying the gas flow rate. For example, the mass flow controller(s) and/or valve(s) 125 may supply more process gas that is converted into plasma in the processing chamber 110, which increases the gas flow rate increases the plasma density.

In the example set forth in FIGS. 1 and 2, the RF plasma generator 120 generates the plasma using inductively coupled plasma (ICP). However, the RF plasma generator 120 may also be configured to generate plasma using capacitively coupled plasma (CCP). When CCP is used, electrodes are arranged in the processing chamber 110, and RF power is applied across the electrodes to generate plasma. In some examples, the gas distribution device or showerhead acts as one electrode and a baseplate of the substrate support acts as the other electrode.

The vacuum controller 130 is connected to the processing chamber 110 to control the pressure in the processing chamber 110. The vacuum controller 130 may provide a vacuum state by evacuating an interior of the processing chamber 110. The vacuum controller 130 may also be used evacuate reactants from the processing chamber 110.

For example, the vacuum controller 130 may include a vacuum pump, a valve, and a pressure sensor or manometer (not shown). The vacuum pump and the valve are connected to the processing chamber 110 and the exhaust 113. The vacuum pump and valve maintain the internal environment of the processing chamber 110 at a constant pressure.

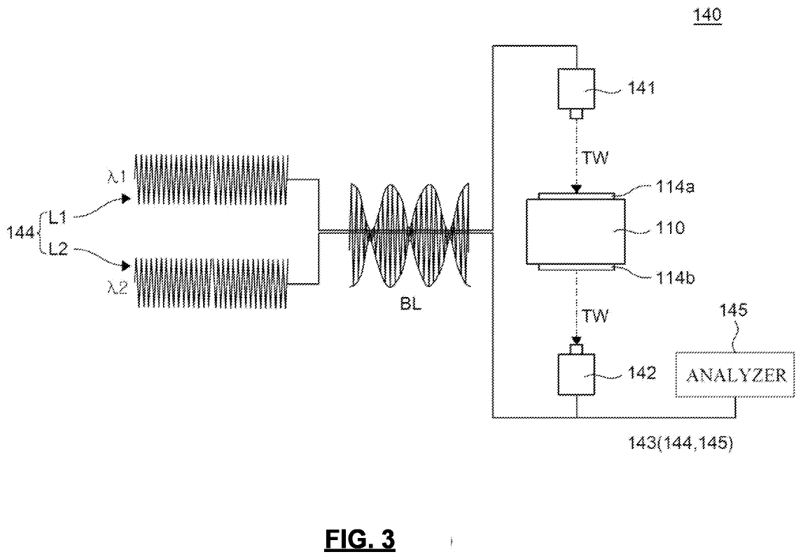

In FIGS. 1 to 3, the terahertz wave measurement system 140 monitors the plasma state in the processing chamber 110 based on the received terahertz waves TW. Characteristics of the terahertz waves TW change as they pass through the plasma in the processing chamber 110. For example, the amplitudes and/or phases of the terahertz waves TW change as they pass through the plasma. In an etch or a deposition process using plasma, the etch depth of the substrate SUB or the thickness of a layer to be deposited may vary depending on the plasma density during the process, respectively.

The terahertz wave measurement system 140 includes an emitter 141, a detector 142, a controller 143, and an alignment stage 146. The controller 143 includes a laser unit 144 and an analyzer 145. The emitter 141 is configured to convert beating light BL transmitted from the laser unit 144 of the controller 143 into terahertz waves TW. For example, the emitter 141 may include a photoconductor that converts the beating light BL into the terahertz waves TW that are output by an antenna. More particularly, the photoconductor of the emitter 141 may convert the beating light BL into a photocurrent, and the photocurrent may be radiated as the terahertz waves TW by the antenna.

The detector 142 is configured to receive the terahertz waves TW transmitted through the interior of the processing chamber 110. For example, the detector 142 may receive the beating light BL from the controller 143 and receive the terahertz waves TW transmitted through the processing chamber 110 using the beating light BL. The detector 142 may measure a change in the received terahertz waves TW based on the beating light BL.

The controller 143 controls the emitter 141 and the detector 142. The controller 143 is configured to determine the density of plasma based on the characteristics of a reference terahertz wave and the characteristics of a measured terahertz wave received by the detector 142. The reference terahertz wave acts as a reference value for detecting changes in one or more characteristics of the measured terahertz wave. In some examples, the controller 143 may store the characteristics of the reference terahertz wave in memory before measuring the plasma density.

The laser unit 144 of the controller 143 is configured to provide the beating light BL to the emitter 141 and the detector 142. The laser unit 144 includes a first laser L1 and a second laser L2 having different phases. The laser unit 144 may transmit the beating light BL mixed with the first laser L1 and the second laser L2 to each of the emitter 141 and the detector 142 through an optical fiber. Accordingly, the beating light BL transmitted to the emitter 141 is converted into the terahertz waves TW to be transmitted through the processing chamber 110. In some examples, the beating light BL is also transmitted to the detector 142 and is used when receiving the terahertz waves TW.

The analyzer 145 is configured to determine the characteristics of the measured terahertz wave received from the detector 142 and the reference terahertz wave. For example, the analyzer 145 may be configured to determine an amplitude difference, a root mean square (RMS) difference, and/or a phase difference between the measured terahertz wave received by the detector 142 and the reference terahertz wave. The analyzer determines the plasma density in the processing chamber 110 in response to the amplitude difference, the RMS difference, and/or the phase difference. In some examples, the analyzer is integrated with the controller 143. Alternately, the analyzer 145 can be implemented as a separate controller.

The alignment stage 146 is configured to control positions of the emitter 141 and the detector 142. The alignment stage 146 is configured to move the emitter 141 and the detector 142 in X-axis, Y-axis, and Z-axis directions to correspond to local areas where the plasma density is to be measured.

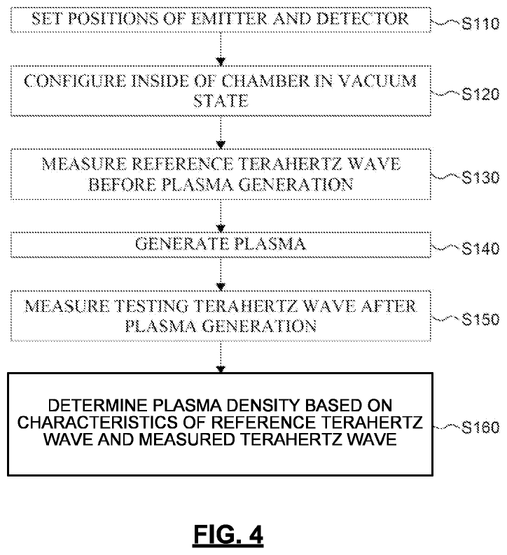

Referring now to FIGS. 4 to 6A, a plasma density measurement using the plasma processing system 100 is described in more detail. In FIG. 4, the positions of the emitter 141 and the detector 142 of the terahertz wave measurement system 140 are set (S110). The positions of the emitter 141 and the detector 142 may be set so that the paths of the reference terahertz wave TWi and the measured terahertz wave TWt from the emitter 141 toward the detector 142 pass through the area where the plasma density is to be monitored.

The interior of the processing chamber 110 is configured in a vacuum state (S120). The vacuum controller 130 may set a vacuum state for plasma generation by evacuating the interior of the processing chamber 110. Next, the reference terahertz wave TWi is measured before plasma generation (S130).

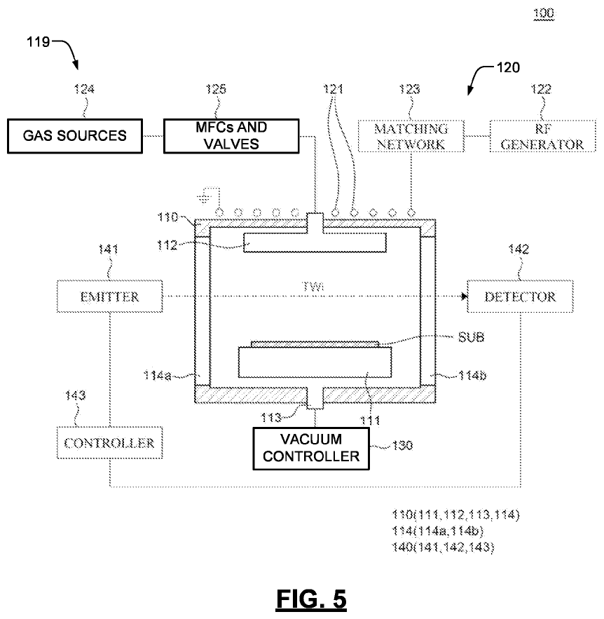

Specifically, referring to FIGS. 4 and 5, the emitter 141 of the terahertz wave measurement system 140 transmits the reference terahertz wave TWi into the processing chamber 110 through the first window 114a. The reference terahertz wave TWi output by the emitter 141 passes through the first window 114a, the interior of the processing chamber 110, and the second window 114b. Finally, the detector 142 arranged on the other side of the processing chamber 110 receives the reference terahertz wave TWi transmitted through the second window 114b.

The analyzer 145 of the controller 143 determines the characteristics of the reference terahertz wave TWi received from the detector 142 and store the characteristics of the reference terahertz wave TWi as a reference value. For example, the analyzer 145 determines an amplitude, an RMS value, and/or a phase of the reference terahertz wave TWi transmitted from the emitter 141 to the detector 142 through the first window 114a, the interior of the processing chamber 110, and the second window 114b and stores the determined amplitude, RMS value, and/or phase as a reference value.

Next, the process gas is supplied to the processing chamber and plasma is struck in the processing chamber 110 (S140). Then, the measured terahertz wave TWt is measured after the plasma generation (S150) while plasma is present. The terahertz wave measurement system 140 measures the characteristics of the measured terahertz wave TWt that passes through the plasma in the processing chamber 110.

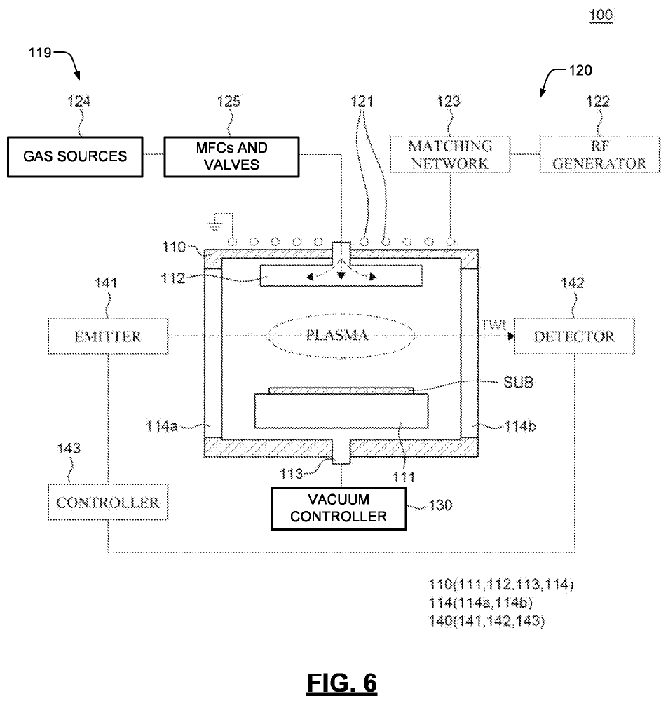

Referring to FIG. 6, the emitter 141 of the terahertz wave measurement system 140 transmits the terahertz wave TWt into the processing chamber 110. The measured terahertz wave TWt passes through the second window 114b via the first window 114a and the interior of the processing chamber 110. In addition, the detector 142 arranged on the other side of the processing chamber 110 receives the terahertz wave TWt after it passes through the interior of the processing chamber 110.

The analyzer 145 of the controller 143 determines the characteristics of the measured terahertz wave TWt received from the detector 142. For example, the analyzer 145 of the controller 143 may determine an amplitude, RMS value, and/or a phase of the measured terahertz wave TWt. The plasma density is then determined based on the characteristics of the reference terahertz wave TWi and the characteristics of the measured terahertz wave TWt (S160). The controller 143 calculates the plasma density by comparing the characteristics of the reference terahertz wave TWi with the characteristics of the measured terahertz wave TWt.

For example, the controller 143 may compare the amplitude of the reference terahertz wave TWi with the amplitude of the measured terahertz wave TWt and determine the plasma density based on an amplitude difference. As the amplitude difference between the reference terahertz wave TWi and the measured terahertz wave TWt increases, the plasma density increases. Conversely, as the amplitude difference decreases, the plasma density decreases. Accordingly, the controller 143 may determine the plasma density based on the amplitude difference between the reference terahertz wave TWi and the measured terahertz wave TWt.

In one embodiment, the controller 143 may compare the RMS value of the reference terahertz wave TWi with the RMS value of the measured terahertz wave TWt and determine the plasma density based on the difference in the RMS value. As the difference in RMS value between the reference terahertz wave TWi and the measured terahertz wave TWt increases, the plasma density increases. Conversely, as the difference in RMS value decreases, the plasma density decreases. Accordingly, the controller 143 may determine the plasma density based on the difference in RMS value between the reference terahertz wave TWi and the measured terahertz wave TWt.

In another embodiment, the controller 143 may compare the phase of the reference terahertz wave TWi with the phase of the measured terahertz wave TWt and determine the plasma density based on a phase difference. The controller 143 may detect a phase difference between the reference terahertz wave TWi and the measured terahertz wave TWt using spline interpolation. As the phase difference between the reference terahertz wave TWi and the measured terahertz wave TWt increases, the plasma density increases. Conversely, as the phase difference decreases, the plasma density decreases. The phase difference between the reference terahertz wave TWi and the measured terahertz wave TWt may be proportional to the plasma density. Accordingly, the controller 143 may determine the plasma density based on the phase difference between the reference terahertz wave TWi and the measured terahertz wave TWt.

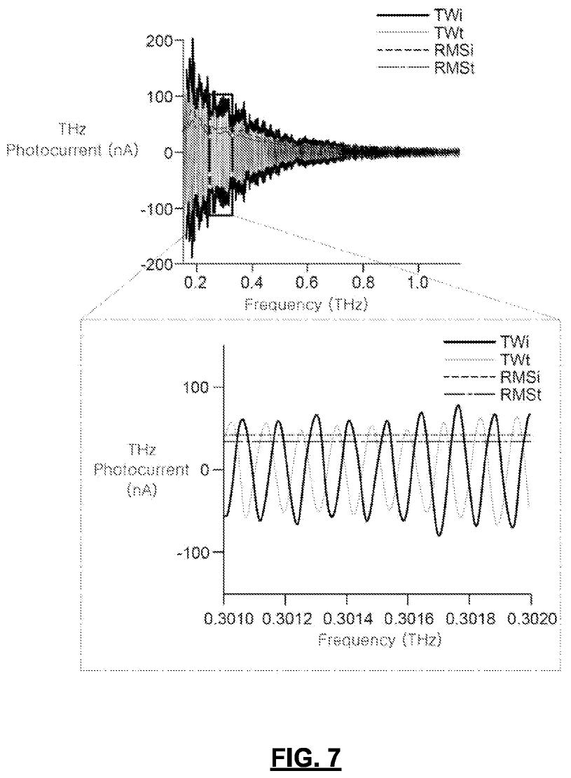

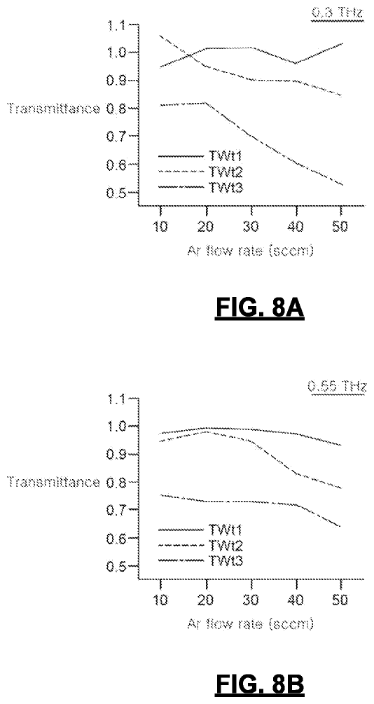

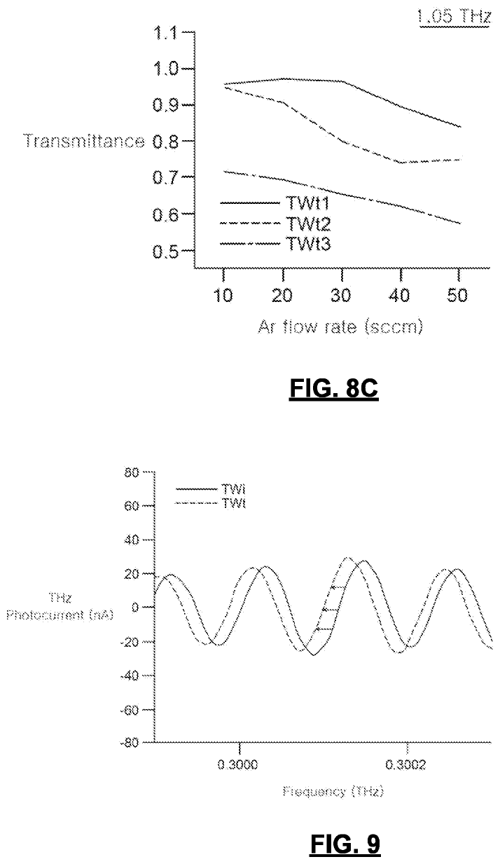

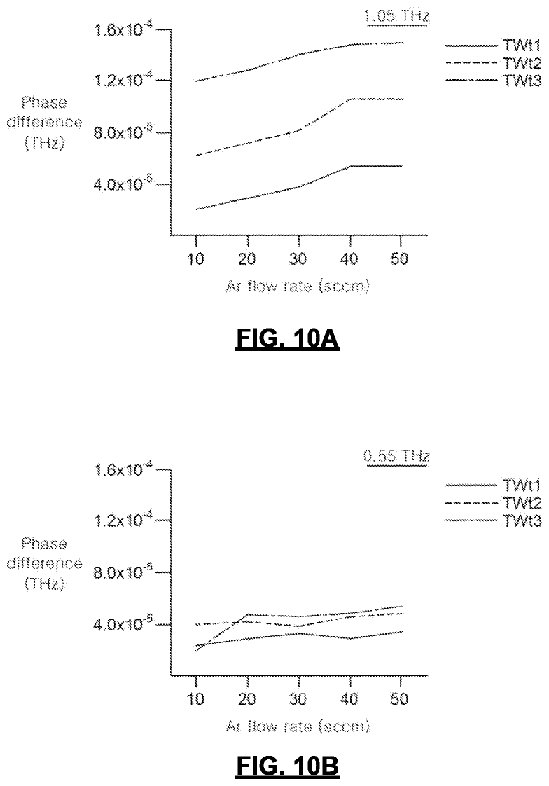

Referring now to FIGS. 7 to 10, measurement results of a reference terahertz wave and a measured terahertz wave of the plasma processing system according to the present disclosure are shown. In FIG. 7, an amplitude difference and an RMS value difference between the reference terahertz wave TWi and the measured terahertz wave TWt is shown. In FIG. 8, changes in transmittance of the measured terahertz wave TWt according to a gas flow rate and power of the RF generator 122 are shown. In FIG. 9, a phase difference between the reference terahertz wave TWi and the measured terahertz wave TWt is shown. In FIG. 10, changes in phase of the measured terahertz wave TWt according to a gas flow rate and power of the RF generator 122 are shown.

The measurement of the terahertz waves may be performed by scanning a specific frequency band during a predetermined period. For example, in FIG. 7, the transmittance may be obtained by scanning a frequency band of 0.3010 THz to 0.3020 THz during a predetermined period (from a low frequency to a high frequency) while changing the frequency.

In some examples, the plasma processing system 100 according to the present disclosure measures the plasma density based on a difference between the amplitudes of the measured terahertz waves TWt and the amplitude of the reference terahertz wave TWi and/or a difference between the RMS values of the measured terahertz waves TWt and the RMS value of the reference terahertz wave TWi. The plasma density increases as the amplitude difference between the measured terahertz waves TWt and the reference terahertz wave TWi increases. The plasma density increases as the difference in RMS value between the measured terahertz waves TWt and the reference terahertz wave TWi increases.

In FIG. 7, photocurrent is shown as a function of frequency for a reference terahertz wave TWi before plasma generation and a measured terahertz wave TWt after plasma generation. If the waveform near a band of about 0.3 THz is enlarged, it can be confirmed that the amplitude of the reference terahertz wave TWi is larger than the amplitude of the measured terahertz wave TWt.

The amplitude and the RMS values of the terahertz waves TW vary according to the plasma density in the processing chamber 110. For example, as the plasma density in the processing chamber 110 increases, the amplitude and the RMS value of the terahertz waves TW transmitted through the processing chamber 110 decrease. The amplitude difference between the measured terahertz wave TWt and the reference terahertz wave TWi is related to (or in some cases proportional to) the plasma density in the processing chamber 110. Accordingly, the plasma processing system 100 according to the present disclosure determines the density of plasma based on an amplitude difference and/or RMS value difference between the measured terahertz wave TWt and the reference terahertz wave TWi.

Referring to FIGS. 8A to 8C, graphs show transmittances of first, second, and third measured terahertz waves TWt1, TWt2, and TWt3 according to a gas flow rate in each of bands of 0.3 THz, 0.55 THz, and 1.05 THz, respectively. The first, second, and third terahertz waves TWt1, TWt2, and TWt3 are measured terahertz waves TWt transmitted through the processing chamber 110 when the power of the RF generator 122 is 50 W, 100 W, and 150 W, respectively. The transmittances of the first, second, and third measured terahertz waves TWt1, TWt2, and TWt3 decrease as the gas flow rate increases. As the gas flow rate increases, the plasma density increases. For example in FIG. 8A, the third measured terahertz wave TWt3 has a transmittance of about 0.8 when the gas flow rate is 10 sccm. When the gas flow rate increases to 30 sccm, the transmittance decreases to about 0.7.

As the power supplied by the RF generator 122 increases, transmittances of the first, second, and third measured terahertz waves TWt1, TWt2, and TWt3 decrease. As the power of the RF generator 122 increases, the induced magnetic field ionizes more gas, and plasma in the processing chamber 110 increases. Therefore, as the power of the RF generator 122 increases, the plasma in the processing chamber 110 increases and the transmittances of the first, second, and third measured terahertz waves TWt1, TWt2, and TWt3 decrease.

For example in FIG. 8B, the transmittance of the first measured terahertz wave TWt1 (transmitted through the processing chamber 110 when the power of the RF generator 122 is 50 W) is higher than the transmittance of the second measured terahertz wave TWt2 (transmitted through the processing chamber 110 when the power of the RF generator 122 is 100 W). In addition, when the power of the RF generator 122 is 150 W, the transmittance of the third measured terahertz wave TWt3 transmitted through the processing chamber 110 is lower than the transmittances of the first measured terahertz wave TWt1 and the second measured terahertz wave TWt2.

Therefore, the terahertz waves TW transmitted through the processing chamber 110 are affected by the plasma density (as determined by the gas flow rate and/or the power of the RF generator 122). As the gas flow rate increases, the plasma density in the processing chamber 110 increases, and the transmittance of the terahertz waves TW transmitted through the processing chamber 110 decreases. As the power of the RF generator 122 increases, the plasma density in the processing chamber 110 increases, and the transmittance of the terahertz waves TW transmitted through the processing chamber 110 decreases.

Referring to FIG. 9, a phase of the terahertz waves TW transmitted through the processing chamber 110 changes in response to the plasma density in the processing chamber 110. As the plasma density in the processing chamber 110 increases, a difference between the phase of the measured terahertz wave TWt and the phase of the reference terahertz wave TWi increases. For example, a peak of the measured terahertz wave TWt measured after plasma generation is shifted to the left of the peak of the reference terahertz wave TWi. Accordingly, as the plasma density increases, a phase difference between the measured terahertz wave TWt and the reference terahertz wave TWi increases.

Referring to FIGS. 10A and 10B, graphs show a phase difference between first, second, and third measured terahertz waves TWt1, TWt2, and TWt3 and a reference terahertz wave TWi in response to gas flow rate in 0.55 THz and 1.05 THz bands, respectively. Each of the first, second and third measured terahertz wave TWti, TWt2, and TWt3 is transmitted through the processing chamber 110 when the power of the RF generator 122 is set to 50 W, 100 W, and 150 W, respectively.

In FIG. 10A, the phase difference between the first measured terahertz wave TWt1 and the reference terahertz wave TWi increases as the gas flow rate increases. The phase differences between the second measured terahertz wave TWt2 and the third measured terahertz wave TWt3 and the reference terahertz wave TWi also increase as the gas flow rate increases. In addition, the third measured terahertz wave TWt3 (having the highest power of the RF generator 122 among the first, second, and third measured terahertz waves TWt1, TWt2, and TWt3) has the largest phase difference from the reference terahertz wave TWi. The first measured terahertz wave TWt1 having the lowest power of the RF generator 122 has the smallest phase difference from the reference terahertz wave TWi.

In FIG. 10B, each of the first, second, and third measured terahertz waves TWt1, TWt2, and TWt3 generally has an increased phase difference from the reference terahertz wave TWi as the gas flow rate increases. Accordingly, as the plasma density in the processing chamber 110 increases as the gas flow rate increases, the phase difference between the measured terahertz wave TWt and the reference terahertz wave TWi increases. In addition, as the power of the RF generator 122 increases, the phase difference between the measured terahertz wave TWt transmitted through the processing chamber 110 and the reference terahertz wave TWi increases.

As the frequency band increases, the phase difference between the measured terahertz wave TWt and the reference terahertz wave TWi increases. In FIG. 10B, the phase difference between the first, second, and third measured terahertz waves TWt1, TWt2, and TWt3 and the reference terahertz wave TWi has a value adjacent to 4×10⁻⁵ THz in a 0.55 THz band. In FIG. 10A, the phase difference between the first, second, and third measured terahertz waves TWt1, TWt2, and TWt3 and the reference terahertz wave has a value up to 1.4×10⁻⁴ THz in the 1.05 THz band higher than 0.55 THz. Accordingly, as the frequency band increases, the phase difference between the measured terahertz wave TWt and the reference terahertz wave TWi increases.

The plasma processing system according to the present disclosure is also configured to monitor the plasma density of a local area within the processing chamber 110. The plasma processing system 100 of the present disclosure may selectively transmit the terahertz waves TW in one or more local areas to locally monitor the plasma density, thereby enabling more accurate plasma monitoring. It is also possible to measure the local plasma density by transmitting the terahertz waves TW only to a specific area, or to detect the average plasma density in the processing chamber 110 by transmitting the terahertz waves TW to a plurality of local areas (for local measurements) and averaging the values (for an overall measurement).

In the plasma processing system 100 according to the present disclosure, it is possible to safely detect the plasma density in a non-contact and non-destructive manner. The terahertz wave measurement system 140 may detect the plasma density in the processing chamber 110 by transmitting the terahertz waves TW through the processing chamber 110. Since the terahertz wave TW is an electromagnetic wave capable of transmitting through non-metallic materials, the terahertz wave measurement system 140 may measure the plasma density without direct contact. In addition, since the terahertz wave TW does not require a transmission medium, there is no need to add a separate medium to the interior of the processing chamber 110. The plasma density can be detected. In addition, the terahertz waves TW are non-ionizing rays (in contrast to ionizing rays such as X-rays) and are harmless to a human body.

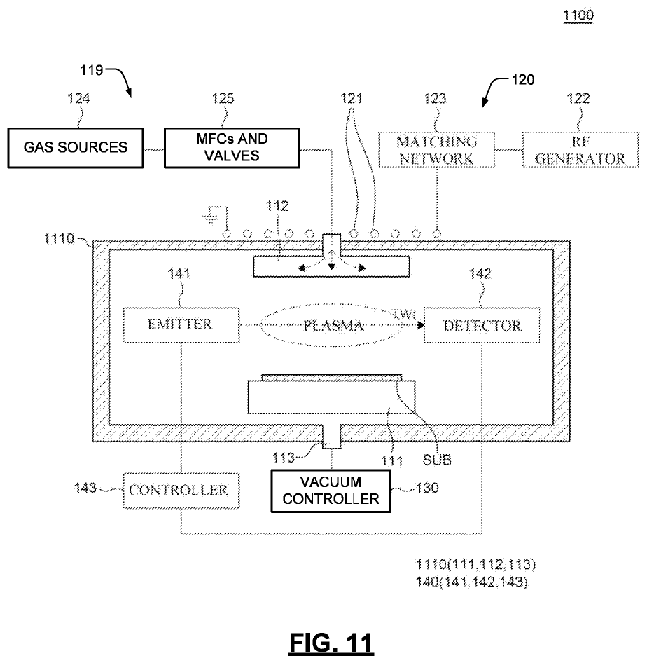

Referring now to FIG. 11, a functional block diagram of a plasma processing system 1100 according to another embodiment of the present disclosure is shown. the plasma processing system 1100 does not include the window. The emitter 141 and the detector 142 of the terahertz wave measurement system 140 are arranged inside of the processing chamber 1110. The emitter 141 and the detector 142 may be arranged in the processing chamber 1110 with the substrate support 111 interposed therebetween. The emitter 141 may be arranged on one side of the substrate SUB, and the detector 142 may be arranged on the other side of the substrate SUB. The terahertz waves TW transmitted from the emitter 141 passes through a portion of the volume located inside of the processing chamber 1110, and the detector 142 may receive the terahertz waves TW transmitted in the processing chamber 1110.

In some examples, the emitter 141 and the detector 142 are embedded in walls of the processing chamber 1110. The terahertz waves TW for detecting the plasma density may have a characteristic of passing through non-metallic materials (while being reflected by metallic materials). Since the emitter 141 and the detector 142 are arranged in the processing chamber 1110, the material of the processing chamber 1110 is not limited.

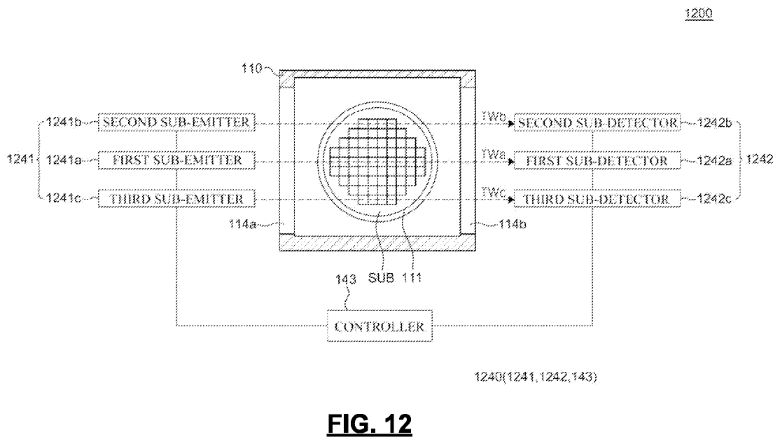

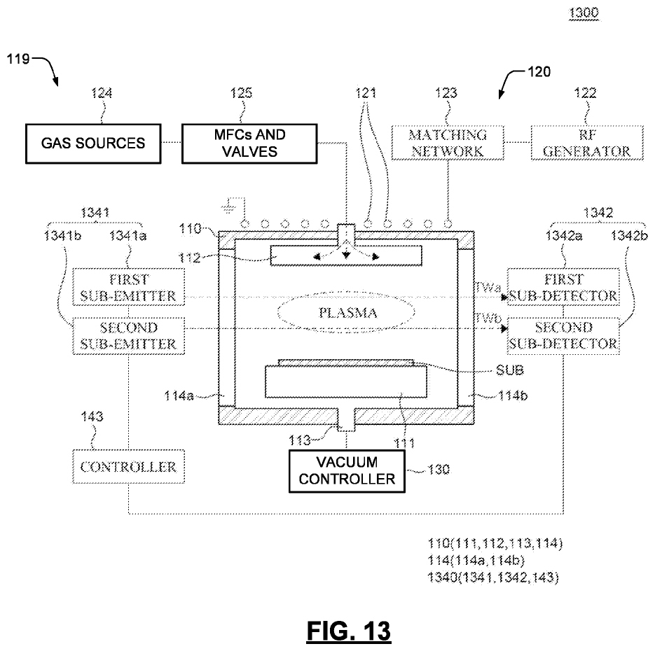

Referring now to FIGS. 12-13, other examples of plasma processing systems are shown. In FIG. 12, the plasma processing system 1200 includes the processing chamber 110, the window 114, the substrate support 111, the substrate SUB, an emitter 1241, a detector 1242, a controller 143, and a terahertz wave measurement unit 1240. In FIG. 13, the plasma processing system 1300 includes the processing chamber 110, the window 114, the substrate support 111, the substrate SUB, an emitter 1341, a detector 1342, a controller 143, and a terahertz wave measurement unit 1340.

In FIGS. 12 and 13, the emitters 1241 and 1341 include a plurality of sub-emitters configured to transmit terahertz waves TW, respectively, and the detectors 1242 and 1342 include a plurality of sub-detectors configured to receive the terahertz waves TW transmitted from each of the plurality of sub-emitters. Each of the plurality of sub-emitters and the plurality of sub-detectors may transmit and receive the terahertz waves TW in one-to-one correspondence with each other.

In FIG. 12, the emitter 1241 includes a first sub-emitter 1241a, a second sub-emitter 1241b, and a third sub-emitter 1241c. The detector 1242 includes a first sub-detector 1242a, a second sub-detector 1242b, and a third sub-detector 1242c. The first sub-emitter 1241a corresponds to the first sub-detector 1242a, the second sub-emitter 1241b corresponds to the second sub-detector 1242b, and the third sub-emitter 1241c corresponds to the third sub-detector 1242c.

For example, the first sub-detector 1242a is configured to receive a terahertz wave TWa output by the first sub-emitter 1241a. A path of the terahertz wave TWa between the first sub-emitter 1241a and the first sub-detector 1242a may be configured to overlap with the center of the substrate SUB. In this case, the path of the terahertz wave TWa transmitted from the first sub-emitter 1241a may overlap with the center of the substrate SUB, and the first sub-emitter 1241a and the first sub-detector 1242a may be used to measure the plasma density at the center of the substrate SUB.

In addition, a path of a terahertz wave TWb between the second sub-emitter 1241b and the second sub-detector 1242b may be configured to overlap with one edge of the substrate SUB. A path of a terahertz wave TWc between the third sub-emitter 1241c and the third sub-detector 1242c may be configured to overlap with the other edge of the substrate SUB. A path of a terahertz wave TWb transmitted from the second sub-emitter 1241b may overlap with one edge of the substrate SUB, and a path of the terahertz wave TWc transmitted from the third sub-emitter 1241c may overlap with the other edge of the substrate SUB. Accordingly, the plasma density may be measured at one edge of the substrate SUB using the second sub-emitter 1241b and the second sub-detector 1242b, and the plasma density may be measured at the other edge of the substrate SUB using the third sub-emitter 1241c and the third sub-detector 1242c.

In FIG. 13, the emitter 1341 includes a first sub-emitter 1341a and a second sub-emitter 1341b, and the detector 1342 includes a first sub-detector 1342a and a second sub-detector 1342b. The first sub-emitter 1341a may correspond to the first sub-detector 1342a, and the second sub-emitter 1341b may correspond to the second sub-detector 1342b.

A first path of the terahertz wave TWa between the first sub-emitter 1341a and the first sub-detector 1342a is arranged between the substrate SUB and the gas distribution device 112. A second path of the terahertz wave TWb between the second sub-emitter 1341b and the second sub-detector 1342b is arranged between the substrate SUB and the gas distribution device 112. The second path is closer to the substrate SUB than the first path. The first path is closer to the gas distribution device 112 than the second path. Accordingly, the plasma density may be measured in an area adjacent to the gas distribution device 112 using the first sub-emitter 1341a and the first sub-detector 1342a. The plasma density may be measured in an area adjacent to the substrate SUB using the second sub-emitter 1341b and the second sub-detector 1342b.

Accordingly, in the plasma processing system 1200 and 1300, the emitters 1241 and 1341 and the detectors 1242 and 1342 of the terahertz wave measurement units 1240 and 1340 are configured to measure the plasma density in various areas in the processing chamber 110. The plurality of sub-emitters and the plurality of sub-detectors may be used to selectively monitor the plasma state of only a partial area inside the processing chamber 110 or monitor the plasma state of the entire area inside the processing chamber 110. The plurality of sub-emitters and the plurality of sub-detectors may be used to characterize the plasma density of the plurality of areas (either simultaneously or sequentially).

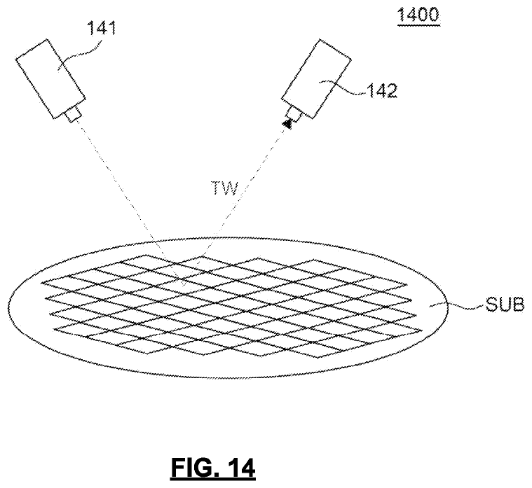

Referring now to FIG. 14, a plasma processing system 1400 is shown to include the substrate SUB, the emitter 141 and the detector 142 of the terahertz wave measurement system 140. The emitter 141 and the detector 142 are arranged on one surface of the substrate SUB. The emitter 141 transmits terahertz waves TW onto a surface of the substrate SUB. The detector 142 receives terahertz waves TW reflected by the surface of the substrate SUB. In this example, the substrate includes a metal layer arranged as an exposed layer or a sublayer. The metal layer reflects the terahertz waves.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “arranged.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.” As used herein, about means +/−10% of a stated value, unless about is otherwise defined.

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the processing chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A plasma processing system comprising:
a processing chamber including a substrate support;
a plasma generator configured to selectively generate plasma in the processing chamber to treat a substrate arranged on the substrate support;
an emitter configured to transmit first terahertz waves through the plasma in the processing chamber; and
a detector configured to receive second terahertz waves corresponding to the first terahertz waves transmitted through the plasma in the processing chamber.

2. The plasma processing system according to claim 1, wherein:
the emitter and the detector are arranged on opposite sides of the processing chamber, and
the processing chamber includes first and second windows located adjacent to the emitter and the detector, respectively.

3. The plasma processing system according to claim 2, wherein the first terahertz waves pass through the first window and into the processing chamber, and the detector is configured to receive the second terahertz waves through the second window.

4. The plasma processing system according to claim 2, wherein an optical axis of the first window is aligned with a path of the first terahertz waves.

5. The plasma processing system according to claim 1, wherein the emitter and the detector are arranged inside of the processing chamber.

6. The plasma processing system according to claim 1, wherein:
the emitter includes a plurality of sub-emitters each configured to generate the first terahertz waves, and
the detector includes a plurality of sub-detectors configured to detect the second terahertz waves from each of the plurality of sub-emitters, respectively.

7. The plasma processing system according to claim 6, wherein:
a first path of the first terahertz waves from one sub-emitter of the plurality of sub-emitters is configured to pass over a center of a substrate, and
a second path of the first terahertz waves transmitted from another sub-emitter of the plurality of sub-emitters is configured to pass over an edge of the substrate.

8. The plasma processing system according to claim 6, wherein a first path of the first terahertz waves from one sub-emitter of the plurality of sub-emitters is closer to an upper portion of the processing chamber than a second path of the first terahertz waves from another sub-emitter of the plurality of sub-emitters.

9. The plasma processing system according to claim 1, wherein:
the emitter and the detector are arranged above a surface of a substrate, and
the first terahertz waves from the emitter are directed at and reflected by the substrate.

10. The plasma processing system according to claim 1, wherein the detector is configured to detect the second terahertz waves using frequency scanning.

11. The plasma processing system according to claim 1, further comprising a controller configured to control the emitter and the detector and to compare one or more characteristics of the second terahertz waves to one or more corresponding characteristics of reference terahertz waves and to estimate plasma density in response to the comparison.

12. The plasma processing system according to claim 11, wherein the controller is configured to:
determine an amplitude difference between the second terahertz waves and the reference terahertz waves, and
calculate the plasma density in the processing chamber based on the amplitude difference.

13. The plasma processing system according to claim 11, wherein the controller is configured to:
determine an RMS value difference between the second terahertz waves and the reference terahertz waves, and
calculate the plasma density in the processing chamber based on the RMS value difference.

14. The plasma processing system according to claim 11, wherein the controller is configured to:
determine a phase difference between the second terahertz waves and the reference terahertz waves, and
calculate the plasma density in the processing chamber based on the phase difference.

15. The plasma processing system according to claim 11, wherein the first terahertz waves are configured as continuous waves.

16. The plasma processing system according to claim 14, wherein the plasma generator includes:
a coil arranged adjacent to the processing chamber; and
an RF generator configured to supply power to the coil.

17. The plasma processing system according to claim 16, wherein the controller is further configured to adjust power supplied by the RF generator to the coil in response to the plasma density.

18. The plasma processing system according to claim 16, wherein the controller is further configured to communicate with a gas delivery system to adjust a gas flow rate to the processing chamber in response to the plasma density.

19. A method for measuring plasma density comprising:
arranging a substrate on a substrate support in a processing chamber;
striking plasma in the processing chamber;
transmitting first terahertz waves through the plasma in the processing chamber;
receiving second terahertz waves corresponding to the first terahertz waves transmitted through the plasma; and
determining plasma density based on characteristics of the second terahertz waves.

20. The method of claim 19, further comprising measuring reference terahertz waves transmitted through the processing chamber before generating the plasma in the processing chamber.

21. The method of claim 20, wherein the determining the plasma density includes at least one of:
comparing an amplitude of the second terahertz waves with an amplitude of the reference terahertz waves; or
comparing a phase of the second terahertz waves with a phase of the reference terahertz waves.

22. The method of claim 21, wherein the plasma density is proportional to a difference between the amplitude of the reference terahertz waves and the amplitude of the second terahertz waves.

23. The method of claim 22, wherein the amplitude of the second terahertz waves is smaller than the amplitude of the reference terahertz waves.

24. The method of claim 22, wherein as the plasma density in the processing chamber increases, a transmittance of the second terahertz waves decreases and the difference between the amplitude of the reference terahertz waves and the amplitude of the second terahertz waves increases.

25. The method of claim 21, wherein the plasma density is proportional to a difference between the phase of the reference terahertz waves and the phase of the second terahertz waves.

26. The method of claim 25, wherein the phase of the second terahertz waves is different than the phase of the reference terahertz waves.

27. The method of claim 25, wherein as the plasma density in the processing chamber increases, a transmittance of the second terahertz waves decreases and the phase difference between the reference terahertz waves and the second terahertz waves increases.

28. The method of claim 19, wherein the receiving the second terahertz waves includes:
outputting the first terahertz waves into the processing chamber from an emitter arranged on one side of the processing chamber; and
detecting the second terahertz waves transmitted through the processing chamber from a detector arranged on the other side of the processing chamber.

29. The method of claim 28, wherein a path of the second terahertz waves between the emitter and the detector passes over the substrate.
